(19) United States
(12) Patent Application Publication
(10) Pub. No.: US 2026/0107479 A1
(43) Pub. Date: Apr. 16, 2026

(54) THREE-DIMENSIONAL SYSTEM-ON-CHIP DEVICE

(71) Applicant: Nexthin Technology, George Town (KY)

(72) Inventors: Tzu-Wei CHIU, Zhubei City (TW); Jen-Hao YEH, Zhubei City (TW)

(21) Appl. No.: 19/277,064

(22) Filed: Jul. 22, 2025

(30) Foreign Application Priority Data
Oct. 11, 2024 (TW) 113138713

(51) Int. Cl. H10B 80/00; H01L 25/065; H01L 25/11; H01L 25/18

(52) U.S. Cl. CPC H10B 80/00; H10W 90/00; H10W 70/60

(57) ABSTRACT

A 3D SoC device includes an intermediate redistribution layer, a lower semiconductor module, and an upper semiconductor module. The intermediate redistribution layer electrically connects the lower semiconductor module to the upper semiconductor module and further connects to an external power source. The lower semiconductor module includes a lower dielectric layer, a lower insulating layer, a plurality of lower conductive posts, a lower chip unit, and a plurality of solder balls. The lower chip unit is composed of a plurality of SoC processing chips located in the lower dielectric layer. The upper semiconductor module includes an upper encapsulating layer, and a plurality of stacked memory units that are embedded in the upper encapsulating layer in a spaced apart manner and that are arranged in an array.

### CROSS-REFERENCE TO RELATED APPLICATION

This application claims priority to Taiwanese Invention Patent Application No. 113138713, filed on Oct. 11, 2024, the entire disclosure of which is incorporated by reference herein.

### FIELD

The disclosure relates to a system-on-chip (SoC), and more particularly to a three-dimensional (3D) SoC device.

### BACKGROUND

Referring to FIG. 1, a conventional face-to-face (F2F) packaged three dimensional (3D) system on chip (SoC) structure 1 includes a redistribution layer 11, a plurality of solder balls 12 attached below the redistribution layer 11, a lower chip module 13 stacked on the redistribution layer 11, and an upper chip module 14 stacked above the lower chip module 13. The lower chip module 13 includes a lower encapsulation layer 131 located above the redistribution layer 11, two lower memory chips 132 that are embedded in and spaced apart by the lower encapsulation layer 131, and a lower processor chip 133 that is embedded in the lower encapsulation layer 131 and that is located between the two lower memory chips 132. The upper chip module 14 includes an upper encapsulating layer 141, two upper processing chips 142 that are embedded in and spaced apart by the upper encapsulating layer 141, and an upper memory chip 143 that is embedded in the upper encapsulating layer 141 and located between the two upper processing chips 142. The lower chip module 13 and the upper chip module 14 are packaged face-to-face (F2F). Additionally, the lower chip module 13 further includes two copper posts 134 that each passes through the lower encapsulation layer 131, that are located near two opposite sides of the lower encapsulation layer 131, and that are both electrically connected to the redistribution layer 11 and the upper processing chips 142 of the upper chip module 14.

In the conventional 3D SoC structure 1, the F2F packaging vertically integrates the upper and lower chip modules 13, 14 into a single packaged structure to occupy a single space on a PCB. The vertically stacking of the upper and lower chip modules provides several benefits such as enhanced processing capabilities, space efficiency, energy efficiency, etc. Therefore, it is desirable for the advanced semiconductor packaging industry to continually improve processing technologies for 3D SoC designs and systems.

### SUMMARY

Therefore, an object of the disclosure is to provide a three-dimensional (3D) system-on-chip (SoC) device that is improved over the prior art.

According to the disclosure, the 3D SoC device includes an intermediate redistribution layer, a lower semiconductor module, and an upper semiconductor module. The intermediate redistribution layer has a top surface and a bottom surface. The lower semiconductor module is located on the bottom surface of the intermediate redistribution layer. The upper semiconductor module is located on the top surface of the intermediate redistribution layer. The intermediate redistribution layer electrically connects the lower semiconductor module to the upper semiconductor module and further connects to an external power source. The lower semiconductor module includes a lower dielectric layer, a lower insulating layer, a plurality of lower conducting posts, and a lower chip unit. The lower dielectric layer is located on the bottom surface of the intermediate redistribution layer. The lower insulating layer is located on a surface of the lower dielectric layer remote from the intermediate redistribution layer, and includes a plurality of openings spaced apart from each other. The plurality of lower conductive posts pass through the lower dielectric layer, and respectively correspond in position to some of the openings. Each of the lower conductive posts 23 have an end that is exposed form the corresponding one of the openings, and another end that is electrically connected with the intermediate redistribution layer. The lower chip unit is composed of a plurality of SoC processing chips and located in the lower dielectric layer. Each of the SoC processing chips are located between adjacent ones of the lower conductive posts. Each of the SoC processing chips includes a first processor redistribution layer, a first processor substrate, a processor active layer, a second processor redistribution layer, a processor dielectric layer, a second processor substrate, and a plurality of second vias. The first processor redistribution layer has a plurality of electrode pads exposed from the openings. The first processor substrate is disposed on the first processor redistribution layer and has a plurality of first vias formed through the first processor substrate. The processor active layer is formed on the first processor redistribution layer and connected to the first processor redistribution layer through the first vias. The second processor redistribution layer is disposed on and electrically connected to the processor active layer. The processor dielectric layer disposed on and connected to the second processor redistribution layer. The second processor substrate is disposed on and connected to the processor dielectric layer. The plurality of second vias pass through the processor dielectric layer and the second processor substrate and each electrically connects with the second processor redistribution layer and the intermediate redistribution layer. The lower semiconductor module further includes a plurality of solder balls which are respectively disposed in the openings and which respectively connect the electrode pads of the processor chip and the lower conductive posts. The upper semiconductor module includes an upper encapsulating layer, and a plurality of stacked memory units. The upper encapsulating layer is formed on the upper surface of the intermediate redistribution layer. The plurality of stacked memory units are embedded in the upper encapsulating layer in a spaced apart manner, and are arranged in an array. Each of the stacked memory units has an upper redistribution layer electrically connected to the intermediate redistribution layer, and a memory chip stack electrically connected to the upper redistribution layer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a conventional face-to-face packaged three dimensional (3D) system on chip (SoC) structure.

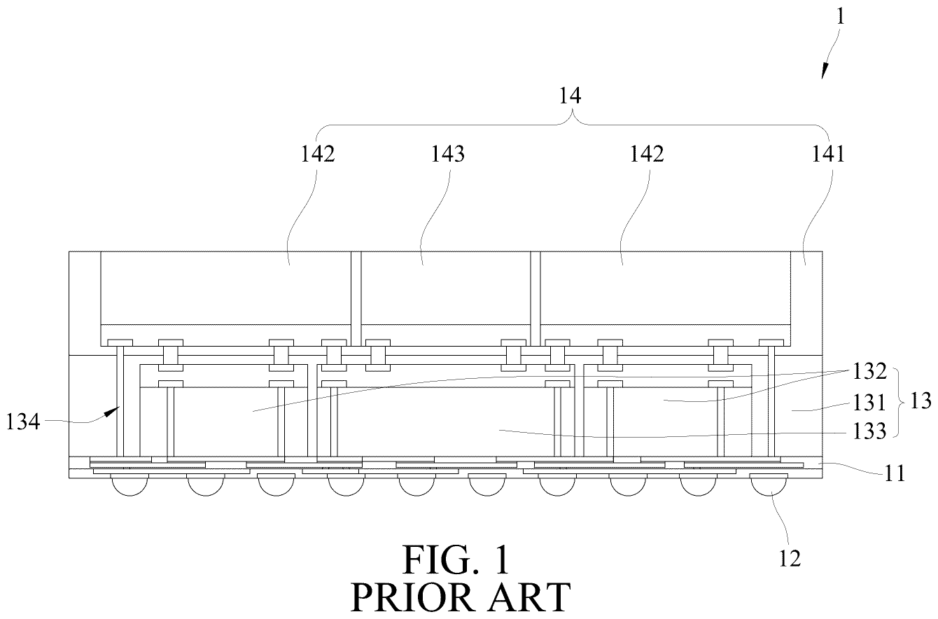

FIG. 2 is a schematic cross-sectional view illustrating a first embodiment of a 3D SoC device according to the present disclosure.

FIG. 3 is a schematic cross-sectional view illustrating a second embodiment of the 3D SoC device according to the present disclosure.

FIG. 4A is a schematic top view illustrating a first variation of the second embodiment showing details of an upper semiconductor module of the 3D SoC device.

FIG. 4B is a schematic top view illustrating a second variation of the second embodiment showing details of the upper semiconductor module.

FIG. 5 is a schematic cross-sectional view illustrating a third embodiment of the present disclosure.

FIG. 6 is a schematic cross-sectional view illustrating a fourth embodiment of the present disclosure.

FIG. 7 is a schematic cross-sectional view illustrating a fifth embodiment of the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

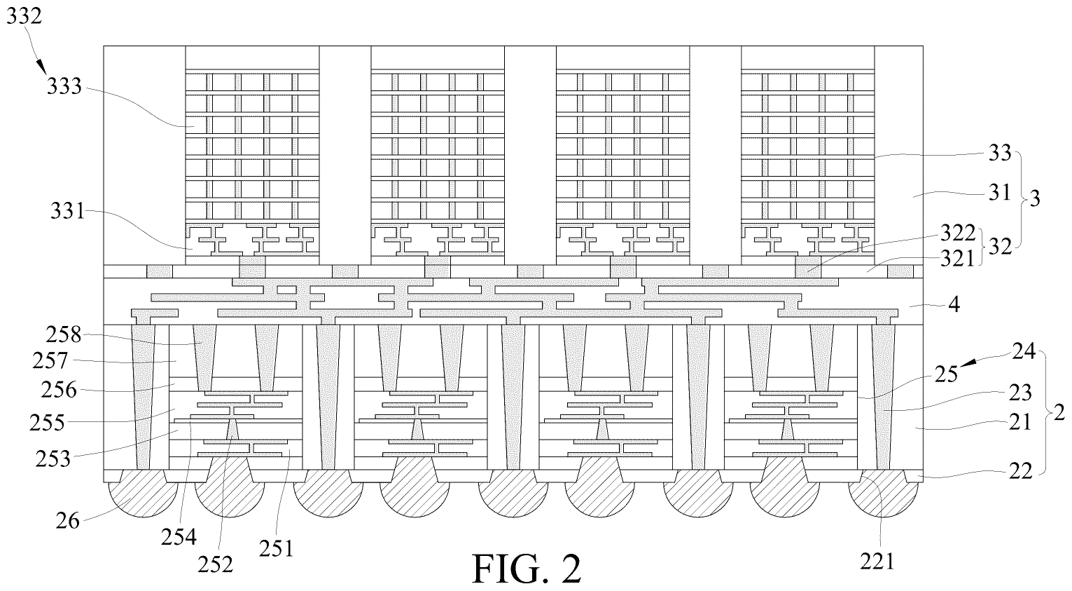

Referring to FIG. 2, a first embodiment of a three-dimensional (3D) system-on-chip (SoC) device includes an intermediate redistribution layer 4, a lower semiconductor module 2, and an upper semiconductor module 3. The intermediate redistribution layer 4 has a top surface and a bottom surface. The lower semiconductor module 2 is located on the bottom surface of the intermediate redistribution layer 4. The upper semiconductor module 3 is located on the top surface of the intermediate redistribution layer 4.

The intermediate redistribution layer 4 electrically connects the lower semiconductor module 2 to the upper semiconductor module 3 and further connects to an external power source.

The lower semiconductor module 2 includes a lower dielectric layer 21, a lower insulating layer 22, a plurality of lower conductive posts 23, a lower chip unit 24, and a plurality of solder balls 26. The lower dielectric layer 21 is located on the bottom surface of the intermediate redistribution layer 4. The lower insulating layer 22 is located on a surface of the dielectric layer 21 oppositely from the intermediate redistribution layer 4, and includes a plurality of openings 221 that are spaced apart from each other. The plurality of lower conductive posts 23 passes through the lower dielectric layer 21, and respectively correspond in position to some of the openings 221. The lower chip unit 24 is located in the lower dielectric layer 21. In this embodiment, the lower insulating layer 22 and the lower dielectric layer 21 are made of dielectric materials such as Si3N4, SiO2, SiON, SiN etc.

Each of the lower conductive posts 23 has an end that is exposed from the corresponding one of the openings 221 and that is connected with a solder ball 26, and another end that is electrically connected with the intermediate redistribution layer 4. Additionally, the lower conductive posts 23 may have a width that substantially approaches 10 μm, and a height that substantially approaches 30 μm. When the 3D SoC device according to the present disclosure is in operation signals may be sent to the upper semiconductor module 3 via the lower conductive posts 23 and the intermediate redistribution layer 4.

The lower chip unit 24 is composed of a plurality of SoC processing chips 25 that are 7 nm/below chips fabricated with 7 nm or even lower processing technology. This means that the SoC processing chips 25 are high end processing chips and exclude other types of SoCs such as memory chips, input/output (I/O) chips, passive components, and low end processing chips. By excluding the other types of SoCs, the interconnect structures that are necessary for the memory chips, I/O chips, passive components, and low end processing chips to operate may be omitted from the design of the lower chip unit 4, and substantial space savings may be achieved. This saved spaced may be instead used to increase the amount of SoC processing chips 25 in the lower chip unit 4 or increase their processing power.

Each of the SoC processing chips 25 is located between adjacent ones of the lower conductive posts 23. Each of the SoC processing chips 25 includes a first processor redistribution layer 251, a first processor substrate 253, a processor active layer 254, a second processor redistribution layer 255, a processor dielectric layer 256, a second processor substrate 257, and a plurality of second vias 258. The first processor redistribution layer 251 of each SoC processing chip 25 has a plurality of electrode pads 251A (only one is shown per SoC processing chip 25) exposed from the openings 221. The first processor substrate 253 of each SoC processing chip 25 is disposed on the first processor redistribution layer 251 and has a plurality of first vias 252 (only one first via 252 is shown per SoC processing chip 25 in the Figures) formed through the first processor substrate 253. The processor active layer 254 of each SoC processing chip 25 is formed on the first processor substrate 253 and connected to the first processor redistribution layer 251 through the first vias 252. The second processor redistribution layer 255 is disposed on and electrically connected to the processor active layer 254. The processor dielectric layer 256 is disposed on and connected to the second processor redistribution layer 255. The second processor substrate 257 is disposed on and connected to the processor dielectric layer 256. The plurality of second vias 258 pass through the processor dielectric layer 256 and the second processor substrate 257 and each electrically connect with the second processor redistribution layer 255 and the intermediate redistribution layer 4. The solder balls 26 of the lower semiconductor module 2 are respectively disposed in the openings 221 for electrical connection with the electrode pads 251A of the SoC processing chips 25 and the lower conductive posts 23. It should be noted that the first vias 252 and the second vias 258 of the SoC processing chips 25 are silicon vias each may have a conductive filling such as copper. Therefore the first vias 252 and the second vias 258 may be used to transfer electrical signals or to form electrical connections. Additionally, each of the first vias 252 in the first processor substrate 253 of the SoC processing chips 25 of the lower semiconductor module 2 has a diameter ranging from 100 nm to 500 nm. The second vias 258 of each of the SoC processing chips 25 of the lower semiconductor module 2 have a diameter that substantially approaches 2 μm and a height that substantially approaches 10 μm. When the 3D SoC device of the present disclosure is in operation, transmission signals may be sent to the upper semiconductor module 3 via the second vias 258 and the intermediate redistribution layer 4.

It is noted that the solder balls 26 respectively correspond in position to the openings 221. Some of the solder balls 26 are respectively electrically connected to the electrode pads 251A of the SoC processing chips 25 exposed from the respective openings 221. The rest of the solder balls 26 are respectively electrically connected to the lower conductive posts 23 exposed from the respective openings 22. The solder balls 26 allow the 3D SoC device to be electrically connected with other electrical components.

In the first embodiment, each of the SoC processing chips 25 of the lower chip unit 24 are high end processors fabricated with 7 nm/below technology. The first processor substrate 253 of each of the SoC processing chips 25 has a thickness that is less than 0.5 μm. Each of the SoC processing chips 25 of the lower chip unit 24 has a thickness that ranges from 10 μm to 200 μm. Each of the solder balls 26 of the lower semiconductor module 2 has a thickness that ranges from 10 μm to 150 μm. The solder balls 26 are spaced apart from each other by a distance that ranges from 20 μm to 200 μm. In this embodiment, when the 3D SoC device is under operation, the first vias 252 of the first processor substrate 253 of each of the SoC processing chips 25 allow electrical connection to a source voltage (Vss) or a drain voltage (Vdd) via a backside of the first processor substrate 253 opposite to the processor active layer 254.

It should be noted that a method for fabricating the SoC processing chips 25 of the present disclosure is more or less similar to the one disclosed in Taiwanese Invention Patent No. Twi779617.

The upper semiconductor module 3 includes an upper encapsulating layer 31, a hybrid bonding layer 32, and a plurality of stacked memory units 33. The upper encapsulating layer 31 is formed on the upper surface of the intermediate redistribution layer 4. The hybrid bonding layer 32 is located in a bottom portion of the dielectric layer 31 (in a side that is close to the intermediate redistribution layer 4). The stacked memory units 33 are embedded in the upper encapsulating layer 31 in a spaced apart manner, and are arranged in an array.

The upper encapsulating layer 31 may be made of a material that is the same as the lower dielectric layer 21, and further details are omitted. The upper encapsulating layer 31 may have a height that substantially approaches 700 μm.

The hybrid bonding layer 32 has a dielectric material layer 321, and a plurality of conducting pads 322 that are embedded in the dielectric material layer 321 that provides electrical conduction between the intermediate redistribution layer 4 and the upper layer chips 33. More specifically, the upper conducting pads 322 are distributed in a spaced apart manner in the dielectric material layer 321 with a pitch (pitch distance) between adjacent upper conducting pads 322 that may range from 2 μm to 9 μm. In some of the upper conducting pads 322, one side of these upper conducting pads 322 is connected to an upper layer chip 33, while another side thereof is connected to the intermediate redistribution layer 4. The hybrid bonding layer 32 allows metal contacts to be embedded in a bottom side of the upper dielectric layer 31. After a heat treatment, the hybrid bonding layer 32 is bonded to the intermediate redistribution layer 4, thereby realizing a heterogeneous junction between the upper dielectric layer 31 and the intermediate redistribution layer 4.

Each of the stacked memory units 33 has an upper redistribution layer 331 electrically connected to the intermediate redistribution layer 4, and a memory chip stack 332 electrically connected to the upper redistribution layer 331. In some embodiments, the memory chip stack 332 of each of the stacked memory units 33 has a plurality of memory chips 333 that are of the same type, and that are vertically stacked. The memory chips 333 are selected from a group consisting of dynamic random-access memory (DRAM), static random-access memory (SRAM), magnetoresistive random-access memory (MRAM), and resistive random-access memory (RRAM). In the first embodiment, the memory chip stack 332 is composed of memory chips 333 that are dynamic random-access memory (DRAM) vertically stacked, and are high bandwidth memory (HBM). However, in other embodiments, the memory chips 333 are not limited to dynamic random-access memory (DRAM).

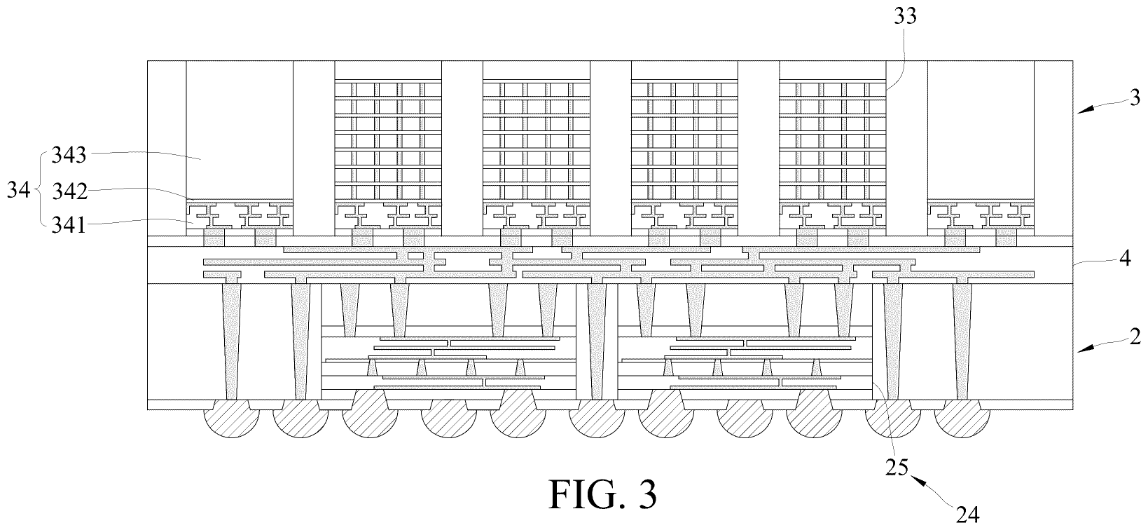

Referring to FIG. 3, a second embodiment of the 3D SoC according to the present disclosure is generally similar to the first embodiment. However, the second embodiment is different in that the upper semiconductor module 3 includes at least two I/O chips 34 that are electrically connected to the array of the stacked memory units 33. In this embodiment, the stacked memory units 33 are arranged in a spaced apart manner in a 1'4 matrix, and the at least two I/O chips 34 are respectively located at two opposite ends of the 1×4 matrix.

Each of the I/O chips 34 has an I/O interconnect layer 341, an I/O active layer 342, and an I/O substrate 343. The I/O interconnect layer 341 is electrically connected to the intermediate redistribution layer 4. The I/O active layer 342 is stacked on a top surface of the I/O interconnect layer 341. The I/O substrate 343 is stacked on a top surface of the I/O active layer 342.

It should be noted that the stacked memory units 33 and the I/O chips 34 in the first embodiment, and the second embodiment are fabricated via a mature integrated circuit (IC) fabrication process. In the current terminology of the IC industry a mature IC fabrication process means the upper layer chips 33 are fabricated with a fabrication process above 7 nm.

It should be note that in the above description that the stacked memory units 33 of the upper semiconductor module 3, and the SoC processing chips 25 of the lower chip unit 24 of the lower semiconductor module 2 are bonded via a face-to-face (F2F) process.

Referring to FIGS. 2 and 3, the 3D SoC device of the first and second embodiments of the present disclosure allocates the SoC processing chips 25, which requires greater signaling input/output, to the lower semiconductor module 2; the 3D SoC device is powered by a back-side power delivery network (BSPDN). This concentrates signaling input/output to the SoC processing chips 25 and decreases signal routing congestion and front-side overcrowding. This is in contrast to the stacked memory units 33 and the I/O chips 34 that are made with mature IC fabrication in the first and second embodiments, where signaling is conducted via the intermediate redistribution layer 4, and that are powered with a front-side power delivery network (FSPDN). This design allows space in the lower semiconductor module to be effectively utilized so that the processing power 3D SoC device of the first and second embodiment may be improved. It should be noted that in the case where the specifications of the SoC processing chips 25 of the lower semiconductor module 2 are changed (e.g., when the SoC processing chips 25 are to be upgraded to a newer specification), only the design of the photomask for the lower semiconductor module 2 will need to be changed, and the design of the photomask for stacked memory units 33 and the I/O chips of the upper semiconductor module 3 may stay the same, thereby providing cost savings to the manufacturer.

The second embodiment may have modified variations. The array of the stacked memory units 33 may have at least two rows or at least two columns, and the upper semiconductor module 3 includes at least two I/O chips 34. One of the at least two I/O chips 34 may be located on one side of the array of the stacked memory units 33, and the other one of the at least two I/O chips 34 may be located on the other side of the array of the stacked memory units 33 that is opposite to the one side of the array of the stacked memory units 33.

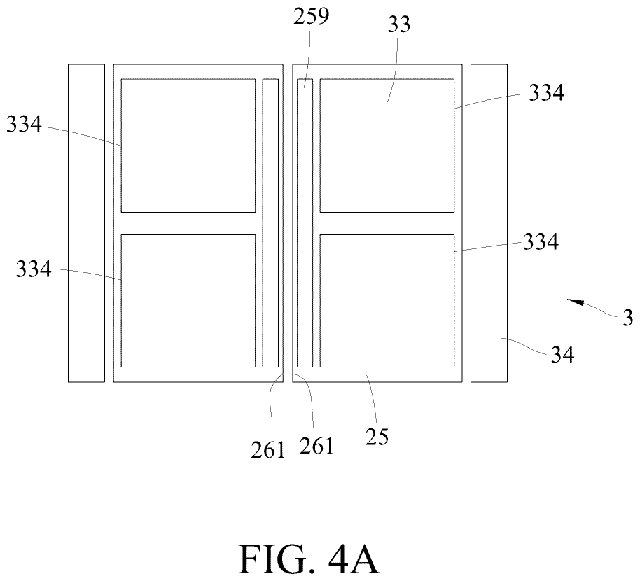

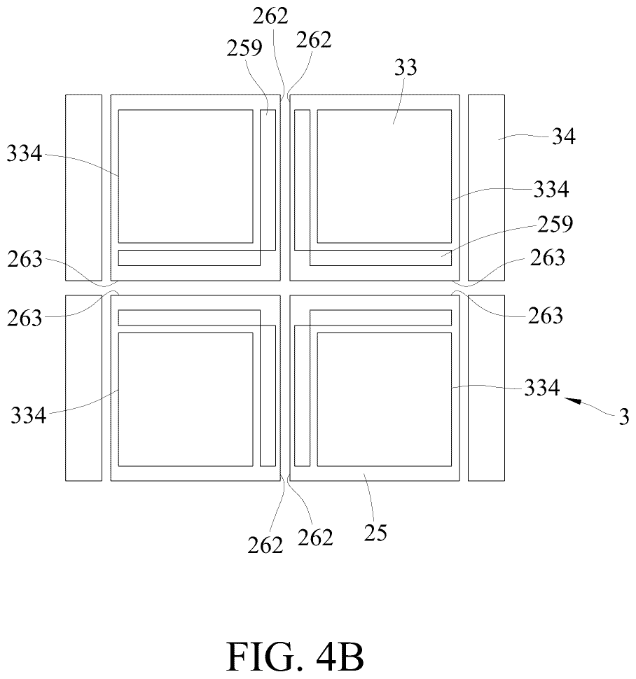

FIG. 4A shows a first variation of the second embodiment. In the first variation, there are two I/O chips 34, and there are four stacked memory units 33 arranged in two pairs. Each pair of the stacked memory units 33 is arranged in a 2×1 matrix array which has two rows and one column. The stacked memory units 33 in two rows of each pair respectively have proximal sides that are proximate to the proximal sides of the stacked memory units 33 in two rows of the other pair. The stacked memory units 33 in the two pairs respectively have distal sides 334 that are opposite to the proximal sides, respectively. One of the two I/O chips 34 connects the distal sides 334 of the stacked memory units 33 in one pair; the other one of the two I/O chips 34 connects the distal sides 334 of the stacked memory units 33 in the other pair. The plurality of SoC processing chips 25 include two SoC processing chips 25. Each of the SoC processing chips 25 are electrically connected to one pair of the stacked memory units 33 via the intermediate redistribution layer 4. The two SoC processing chips 25 respectively have proximal sides 261 connected to each other via a D2D (Tx/Rx) interface 259 for transmission and reception.

Referring to FIG. 4B, in a second variation of the second embodiment, the upper semiconductor module 3 includes four stacked memory units 33 which are in a 2×2 matric array having two rows and two columns, and four I/O chips 34. Each of the stacked memory units 33 has a proximal side that is connected to a proximal side of an adjacent one of the stacked memory units 33 and a distal side 334 connected to one of the four I/O chips 34. The plurality of SoC processing chips 25 include four SoC processing chips 25 that are in a 2×2 matrix array. Each of the four SoC processing chips 25 is electrically connected to one of the four stacked memory units 33 via the intermediate redistribution layer 4. Each of the plurality of SoC processing chips 25 has a first side 262 connected to a first side 262 of an adjacent one of the plurality of SoC processing chips 25 via a D2D (Tx/Rx) interface 259, and a second side 263 connected to the second side 263 of another adjacent one of the plurality of SoC processing chips via another D2D (Tx/Tx) interface 259.

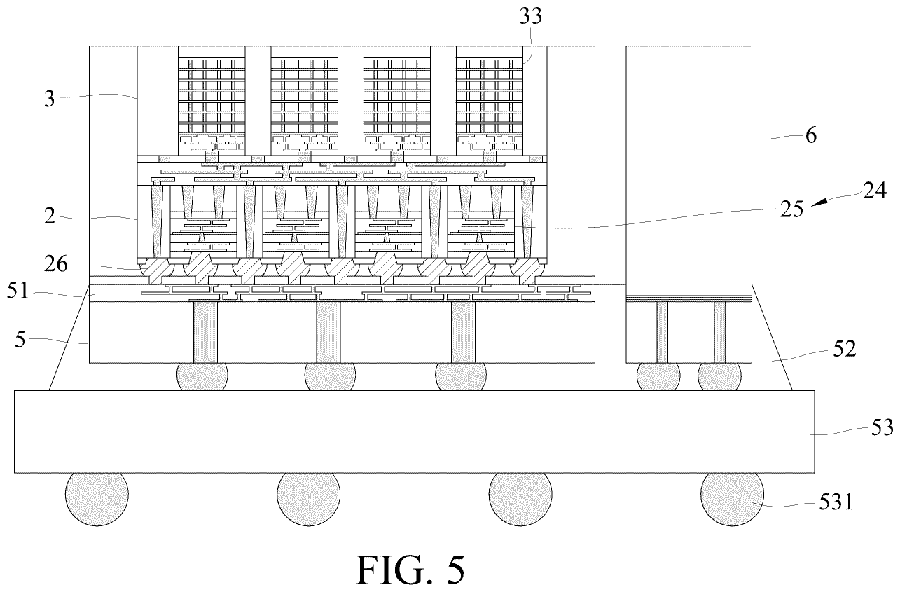

FIG. 5 shows a third embodiment of the 3D SoC device according to the present disclosure. The third embodiment is generally similar to the first embodiment. However the third embodiment different from the first embodiment in that the third embodiment is packaged in a 2.5D chip-on-wafer-on-substrate (CoWoS) packaging, and the 3D SoC device includes a silicon interface layer 5, a first RDL layer 51, a circuit board 53, and a silicon-photonics (SiPh) module 6. The silicon interface layer 5 is electrically connected to the solder balls 26 via the first RDL layer 51. The first RDL layer 51 is located above the silicon interface layer 5 and is bonded to the solder balls 26. The circuit board 53 is located below and bonded to the silicon interface layer 5, is electrically connected to the solder balls 26, and includes a first ball grid array (BGA) unit 531. The SiPh module 6 is bonded to the circuit board 53. A first encapsulant 52 is used to package the silicon interface layer 5, the upper semiconductor module 3, and the lower semiconductor module 2 together.

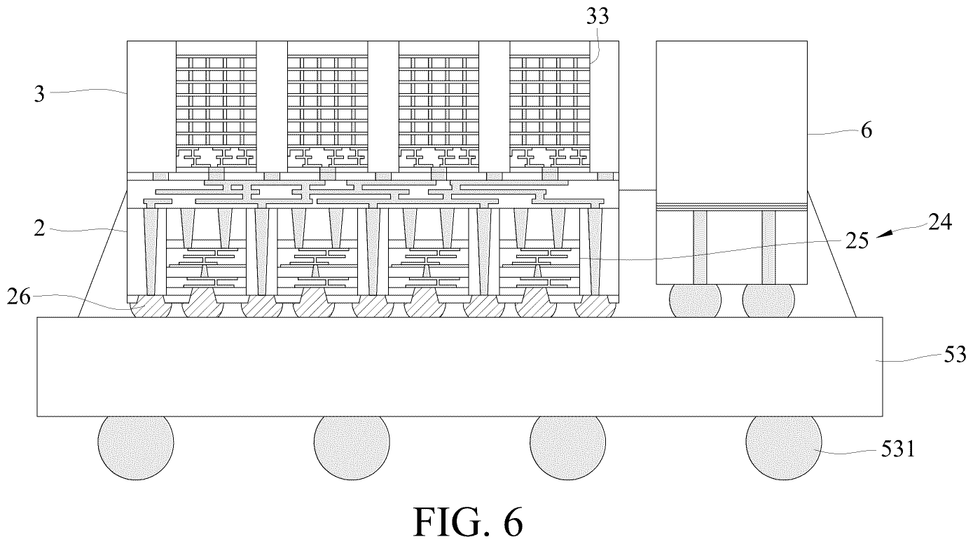

FIG. 6 shows a fourth embodiment of the 3D SoC device according to the present disclosure. The fourth embodiment is generally similar to the third embodiment. However, in the fourth embodiment, the circuit board 53 is physically and electrically directly connected to the solder balls 26, and the silicon interface layer 51 in the third embodiment is omitted. Additionally the SiPh module 6 is bonded to the circuit board 53.

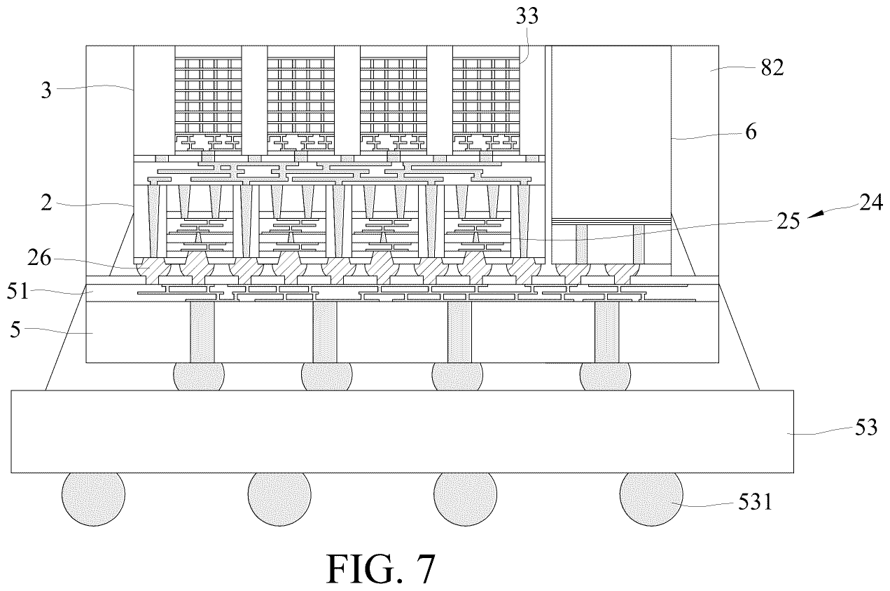

FIG. 7 shows a fifth embodiment of the 3D SoC device according to the present disclosure. The fifth embodiment is similar to the third embodiment; however, the fifth embodiment is different in that it includes a second encapsulant 82 which is used to package silicon interface layer 5, the upper semiconductor module 3, the lower semiconductor module 2, and the SiPh module 6 together.

In summary of the above, in the 3D SoC device according to the present disclosure, the lower chip unit 24 of the lower semiconductor module 2 includes only SoC processing chips 25 (high end processing chips). Therefore, space in the lower semiconductor module 2 need not be occupied by I/O chips, memory chips, or physical layers. Instead, all space in the lower semiconductor module may be exclusively used for SoC processing chips 25 (high end processing chips) which may improve space efficiency and computational power of the lower semiconductor module 2. Furthermore, the SoC processing chips 25 of the lower chip unit 24 of the lower semiconductor module 2 may be powered via BSPDN which lessens routing congestion, and may thereby allow the processing chips 25 to run with maximum computational performance.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A three-dimensional (3D) system-on-chip (SOC) device comprising:
an intermediate redistribution layer having a top surface and a bottom surface;
a lower semiconductor module located on said bottom surface of said intermediate redistribution layer; and
an upper semiconductor module located on said top surface of said intermediate redistribution layer;
wherein said intermediate redistribution layer electrically connects said lower semiconductor module to said upper semiconductor module and further connects to an external power source;
wherein said lower semiconductor module includes:
a lower dielectric layer that is located on said bottom surface of said intermediate redistribution layer;
a lower insulating layer that is located on a surface of said dielectric layer oppositely from said intermediate redistribution layer, and that includes a plurality of openings spaced apart from each other;
a plurality of lower conductive posts that pass through said lower dielectric layer, and that respectively correspond in position to some of said openings, each of said lower conductive posts having an end that is exposed from the corresponding one of said openings, and another end that is electrically connected with said intermediate redistribution layer; and
a lower chip unit composed of a plurality of SoC processing chips, and located in said lower dielectric layer, each of said SoC processing chips being located between adjacent ones of said lower conductive posts;
wherein each of said SoC processing chips includes:
a first processor redistribution layer which has a plurality of electrode pads exposed from said openings;
a first processor substrate which is disposed on said first processor redistribution layer and which has a plurality of first vias formed through said first processor substrate;
a processor active layer formed on said first processor substrate and connected to said first processor redistribution layer through said first vias,
a second processor redistribution layer disposed on and electrically connected to said processor active layer;
a processor dielectric layer disposed on and connected to said second processor redistribution layer;
a second processor substrate disposed on and connected to said processor dielectric layer; and
a plurality of second vias which pass through said processor dielectric layer and said second processor substrate and each of which electrically connects with said second processor redistribution layer and said intermediate redistribution layer;
wherein said lower semiconductor module further includes a plurality of solder balls which are respectively disposed in said opening and which respectively electrically connect said electrode pads of said processor chip and said lower conductive posts; and
wherein said upper semiconductor module includes:
an upper encapsulating layer formed on said upper surface of said intermediate redistribution layer, and
a plurality of stacked memory units that are embedded in said upper encapsulating layer in a spaced apart manner, and that are arranged in an array, each of said stacked memory units having an upper redistribution layer electrically connected to said intermediate redistribution layer, and a memory chip stack electrically connected to said upper redistribution layer.

2. The 3D SoC device as claimed in claim 1, wherein each of said first vias in said first processor substrate of said lower semiconductor module has a diameter ranging from 100 nm to 500 nm.

3. The 3D SoC device as claimed in claim 1, wherein each of said SoC processing chips of said lower chip unit are fabricated with a 7 nm/below process technology.

4. The 3D SoC device as claimed in claim 1, wherein said first processor substrate of each of said SoC processing chips has a thickness that is less than 0.5 μm.

5. The 3D SoC device as claimed in claim 1, wherein said memory chip stack of each of said stacked memory units has a plurality of memory chips that are of the same type, and that are vertically stacked.

6. The 3D SoC device as claimed in claim 5, wherein said memory chips are selected from a group consisting of dynamic random-access memory (DRAM), static random-access memory (SRAM), magnetoresistive random-access memory (MRAM), and resistive random-access memory (RRAM).

7. The 3D SoC device as claimed in claim 1, wherein said upper semiconductor module further includes at least two I/O chips electrically connected to said array of said stacked memory units.

8. The 3D SoC device as claimed in claim 7, wherein:
said array of said stacked memory units has at least two rows or at least two columns; and
one of said at least two I/O chips is located on one side of said array of said stacked memory units, and the other one of said at least two I/O chips is located on the other side of said array of said stacked memory units that is opposite to said one side of said array of said stacked memory units.

9. The 3D SoC device as claimed in claim 1, further comprising a silicon interface layer that is electrically connected to said solder balls.

10. The 3D SoC device as claimed in claim 1, further comprising a circuit board that is electrically connected to said solder balls.

11. The 3D SoC device as claimed in claim 7, wherein:
said plurality of stacked memory units include two pairs of stacked memory units, each pair of said stacked memory units being arranged in a 2×1 matrix array which has two rows and one column;
said stacked memory units in two rows of each of the two pairs respectively have proximal sides that are proximate to said proximal sides of said stacked memory units in two rows of the other one of the two pairs, the two pairs of said stacked memory units respectively have distal sides that are opposite to said proximal sides, respectively;
one of said at least two I/O chips connects said distal sides of said stacked memory units in one of the two pairs, the other one of said at least two I/O chips connecting said distal sides of said stacked memory units in the other one of the two pairs;
said plurality of SoC processing chips include two SoC processing chips, each of said two SoC processing chips being electrically connected to said stacked memory units in one of the two pairs via said intermediate redistribution layer, said two SoC processing chips respectively having proximal sides connected to each other via a D2D (Tx/Rx) interface for transmission and reception.

12. The 3D SoC device as claimed in claim 7, wherein:
said plurality of stacked memory units include four stacked memory units which are in a 2×2 matrix array having two rows and two columns;
said at least two I/O chips include four I/O chips;
each of said stacked memory units has a proximal side that is connected to a proximal side of an adjacent one of said stacked memory units, and a distal side connected to one of said four I/O chips;
said plurality of SoC processing chips include four SoC processing chips that are in a 2×2 matrix array, each of said four SoC processing chips being electrically connected to one of said four stacked memory units via said intermediate redistribution layer; and
each of said plurality of SoC processing chips has a first side connected to said first side of an adjacent one of said plurality of SoC processing chips via a D2D (Tx/Rx) interface, and a second side connected to said second side of another adjacent one of said plurality of SoC processing chips via another D2D (Tx/Rx) interface.
